(19) United States
(12) Patent Application Publication
(10) Pub. No.: US 2011/0019760 A1
(43) Pub. Date: Jan. 27, 2011

(54) Methods and Systems for Reducing Supply and Termination Noise

(75) Inventor: Huy M. Nguyen, San Jose, CA (US)

Correspondence Address: SILICON EDGE LAW GROUP, LLP, 6601 KOLL CENTER PARKWAY, SUITE 245, PLEASANTON, CA, 94566, US

(73) Assignee: Rambus Inc., Los Altos, CA (US)

(21) Appl. No.: 12/833,835

(22) Filed: Jul. 9, 2010

Related U.S. Application Data
(60) Provisional application No. 61/227,204, filed on Jul. 21, 2009.

(51) Int. Cl. H04L 1/02; H03K 17/687; H03K 5/22; H04L 25/49

(52) U.S. Cl. 375/267; 327/437; 327/89; 375/297; 375/347

(57) ABSTRACT

A transmitter expresses continuous-time signals on alternate, parallel channels with reference to different supply voltages such that the signals on alternate channels have different common-mode voltages. At the transmitter, expressing the symbols using alternate supply voltages limits the maximum supply current used to express the signals and to transition between adjacent symbol sets. Limiting supply current ameliorates problems associated with simultaneous switching noise (SSN). At the receiver, the different common-mode voltages tend to balance the current to and from termination nodes, and consequently place reduced stress on a reference voltage. Providing different common-mode voltages on alternate channels may additionally reduce cross-talk between channels.

### FIELD

The invention relates to the suppression of power-supply and reference-voltage noise in and between integrated circuits.

### BACKGROUND

Transmitters and receivers in typical high-speed digital communication systems communicate data as series of symbols, each symbol representing a different logical value for a time period called a “unit interval,” or “UI.” Commonly, each symbol represents a single binary “bit” that represents either a logic one as a relatively high voltage or a logic zero as a relatively low voltage. A transmitter can thus convey data as bit patterns expressed as a voltage signal that transitions between the relatively high and low voltage levels. Adjacent like-symbols are represented by maintaining the same voltage over multiple UIs, whereas adjacent dissimilar symbols are represented by transitioning between voltage levels between UIs. A receiver can recover the bit patterns, and therefore the original data, by comparing the voltage signal against a reference voltage to distinguish between the high and low voltage levels during each UI.

Transmitters draw current from a power supply to express voltage levels and to transition between them. In high-speed systems, most supply current is drawn during the transitions. Patterns with few transitions thus tend to draw less supply current than transition-rich patterns. Average supply current thus varies with the data pattern being communicated.

Power supplies are imperfect. For example, the lines and pads used to convey supply current exhibit parasitic resistive, inductive, and capacitive impedances. Unfortunately, this impedance and the data-dependent supply current together cause the supply voltage to fluctuate. The reference voltage employed by the receiver can also be affected. The resulting supply and reference noise effect signal integrity and therefore limit performance.

Many systems support higher data rates by transmitting multiple data streams in parallel. For example, eight data channels may transmit eight data streams in parallel to communicate eight bits per UI. Unfortunately, simultaneously transmitting and recovering multiple bits exacerbates the problems of data-dependent supply noise because supply current can vary dramatically between UIs. In a simple eight-bit example, from zero to eight bits might change values from one UI to the next. The resulting problem is referred to by those of skill in the art as simultaneous switching noise, or SSN. Such instability can introduce significant errors in supply and reference voltages, and thus adversely impact performance.

Efforts to minimize SSN have focused in two general areas of improvement. The first attempts to reduce supply impedance and improve voltage regulation to reduce a system's sensitivity to changing supply current. Unfortunately, these improvements require complex and area-intensive circuitry. The second area of improvement encodes the transmitted data into more or less balanced symbol patterns to reduce changes in supply current between UIs. These solutions include the so-called 8b/10b code that maps eight-bit symbols into ten-bit symbols that draw a relatively constant supply current over time. While effective, this coding scheme requires the insertion of two additional bits for each eight-bit byte, and consequently reduces speed performance. Parallel systems address SSN using a coding scheme called “dynamic bus inversion,” or DBI. In an eight-bit example, a system employing DBI uses an extra channel to convey a ninth bit, or DBI bit, that inverts a subset of eight-bit data bytes that would otherwise draw the most supply current. Some DBI schemes are capable of reducing the total current drawn from a supply voltage to half that of a similar non-DBI systems. This improvement comes at the cost of additional circuit complexity and an additional communication channel, both of which increase cost.

### BRIEF DESCRIPTION OF THE DRAWINGS

The subject matter disclosed is illustrated by way of example, and not by way of limitation, in the figures of the accompanying drawings and in which like reference numerals refer to similar elements and in which:

FIG. 1 depicts a communication system 100 in which a transmitter 105 conveys four discrete signals, bit streams Di1(n)-Di4(n), as parallel, continuous-time signals Da1(t)-Da4(t) to a receiver 110 via four communication channels 115.

FIG. 2 is a waveform diagram 200 depicting amplified, continuous-time data streams Da1(t) and Da2(t) from transmitter 105 of FIG. 1.

FIG. 3 depicts a system 300 in accordance with an embodiment that is easily rendered compatible with receivers that support conventional communication schemes.

FIGS. 4A-4B illustrate the behavior of continuous-time signals Da[1:8](t) of FIG. 3 in transitioning from the resting state responsive to transitions of discrete signals Di[1:8](n).

FIGS. 5A-5B illustrate transitions of eight-bit continuous-time signals Da[1:8](t) from the resting state (all amplifiers T1-T8 off) to other states, and shows how such transitions impact the current Iterm at receiver 310.

FIG. 6 depicts a driver configuration 600 in accordance with another embodiment.

### DETAILED DESCRIPTION

FIG. 1 depicts a communication system 100 in which a transmitter 105 conveys four related discrete signals, bit streams Di1(n)-Di4(n), as parallel, continuous-time signals Da1(t)-Da4(t) to a receiver 110 via four communication channels 115. In accordance with this embodiment, transmitter 105 expresses the continuous-time signals with reference to different supply voltages. As a consequence, signals Da1(t) and Da2(t) exhibit different common-mode voltages on channels 115(1) and 115(2), respectively, and signals Da3(t) and Da4(t) exhibit different common-mode voltages on channels 115(3) and 115(4), respectively. Expressing the output signals in this manner provides advantages at both transmitter 105 and receiver 110. At the transmitter, expressing the symbols using different supply voltages limits the maximum supply current used to express signals Da1(t)-Da4(t) and to switch between adjacent symbol sets. Limiting the maximum and switching supply currents ameliorates problems associated with SSN. At receiver 110, the different common-mode voltages tend to balance the current to and from a common termination node 150, and consequently place reduced stress on a reference voltage Vio/2 on termination node 150. Providing different common-mode voltages on alternate channels may additionally reduce cross-talk between channels.

Transmitter 105 may be a memory component or part of a memory component that conveys data, addresses, and commands. Transmitter 105 includes a data source 120 that provides the parallel streams Di1(n)-Di4(n), and that may include e.g. a serial-to-parallel converter. A pair of pull-up amplifiers T1 and T3 amplify data streams Di1(n) and D3(n), respectively, using a relatively high supply voltage Vio on a like-named supply node to produce a respective pair of amplified versions of bit streams Di1(n) and Di3(n) as signals Da1(t) and Da3(t). In doing so, amplifiers T1 and T3 periodically draw respective supply currents Ip1 and Ip2 from supply node Vio. A pair of pull-down amplifiers T2 and T4 amplify data streams Di2(n) and Di4(n), respectively, using a relatively low voltage Gnd on a second supply node to produce a respective pair of amplified versions of the bit streams as continuous-time signals Da2(t) and Da4(t). Amplifiers T1 and T3 periodically send respective supply currents In1 and In2 to supply node Gnd. The amplifiers are single MOS transistors in this example, but may be implemented differently in other embodiment. At a minimum, each amplifier will have a control terminal (e.g. a gate) coupled to a signal source, a first current-handling terminal (e.g. a source) coupled to a supply node, and a second current-handling terminal (e.g. a drain) coupled to one of the channels. Although only four channels are shown connected to transmitter 105 for ease of illustration, transmitter 105 may support more or fewer channels in other embodiments.

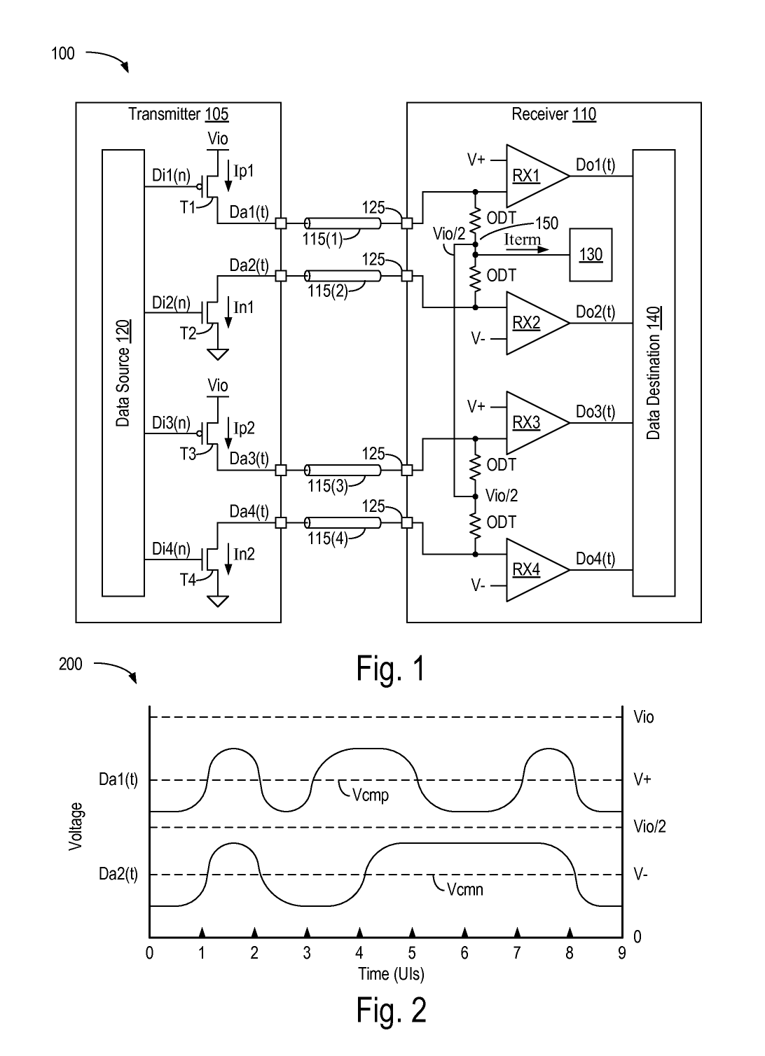

FIG. 2A is a waveform diagram 200 depicting amplified, continuous-time data streams Da1(t) and Da2(t) from transmitter 105 of FIG. 1. The vertical axis shows a range of voltages from zero (Gnd) to supply voltage Vio; the horizontal axis represents time, as measured in unit intervals, or UIs, each of which represents the minimum time interval between symbol transitions, As shown, output signal Da1(t) has a first common-mode voltage Vcmp and does not fall below a voltage that is about half the supply voltage Vio/2, whereas output signal Da2(t) has a second, lower common-mode voltage Vcmn and does not rise above voltage Vio/2. The waveforms of FIG. 2A are idealized. Actual waveforms can include transient voltage overshoot and undershoot artifacts due to e.g. inductive current spikes that can occur when switching between voltage levels. Such transient artifacts are ignored when measuring voltage swing. In some embodiments the voltage swing of each signal Da#(t) is less than the difference between the respective common-mode voltage and the nearest supply node. For example, the amplitude of signal Da1(t) would be less than the difference between the voltage on node Vio and common-mode voltage Vcmp.

The difference between common-mode voltage Vcmp and voltage Vio/2 is less than half the voltage swing of signal Da1(t), and the difference between voltage Vio/2 and common-mode voltage Vcmn is less than half of the voltage swing of signal Da2(t). Output signals Da1(t) and Da2(t) thus do not overlap in the voltage space. The remaining two data signals Da3(t) and Da4(t) have the similar characteristics and are thus omitted for ease of illustration. Expressing signals on alternate channels using non-overlapping voltage ranges reduces cross-talk, and thus improves signaling performance.

To further explain this advantage of transmitter 105, consider a conventional transmitter having four drivers each including a pull-up amplifier and a pull-down amplifier coupled in series between Vio and ground. For each driver, the pull-up amplifier can be used to drive a logic “1” over a link and the pull-down amplifier can be used to drive a logic “0” over the same link. In a worst case scenario, each driver is driving a logic “0” onto its respective link so that all four pull-down amplifiers are “on” while all four pull-up amplifiers are “off” at the same time. This results in a maximum supply current to ground, four times the maximum current i drawn by each pull-down amplifier, and a minimum supply current from node Vio. If, in the next unit interval, each driver drives a logic “1” so that all four pull-down amplifiers change at about the same time from being “on” to being “off” while all four pull-down amplifier change at about the same time from being “off” to being “on”, the supply current at the ground node could change from the maximum supply current, or 4i, to about zero, while supply current at the Vio node could change from zero to a maximum supply current of 4i.

Now consider transmitter 105 in FIG. 1. Each amplifier is assumed to draw the same maximum current i as in the prior example. That is, the magnitude of each of currents Ip1, In1, Ip2, and In2 peaks at current i when its corresponding amplifier is on. Only two amplifiers T1 and T3 draw currents from node Vio, so a maximum supply current from that node is just two times the maximum current i drawn by each amplifier, or 2i, rather than 4i as in the prior example. A maximum supply current to the ground node is likewise 2i in the example of FIG. 1, or the sum of currents In1 and In2 when amplifiers T2 and T4 are both on. The supply noise is thus distributed between the two supply nodes, each of which exhibits a capacitance that tends to filter supply noise. The additional filter capacity of a second supply node and the lower peak current levels work together to reduce signal degradation at the transmitter 105.

Returning to FIG. 1, receiver 110 supports a balanced termination scheme that takes advantage of the offset common-mode voltages of signals Da1(t)-Da4(t) to reduce deleterious noise on a termination node Vio/2. Receiver 110 includes four receive amplifiers RX1, RX2, RX3, and RX4 connected to respective channels 115(1), 115(2), 115(3), and 115(4) via data terminals 125 (e.g., signal pads that commonly provide external access to integrated circuits). Each amplifier includes a data node coupled to a respective data terminal 125 and a reference node coupled to either a first reference node V+, for incoming data signals having the relatively high common-mode voltage Vcmp, or to a second reference node V−, for incoming data signal having the relatively low common-mode voltage Vcmn. The data nodes for each amplifier are terminated to termination node Vio/2 via a respective termination impedance ODT. A data destination 140, such as a multiplexing/demultiplexing block, samples output signals Do1(t)-Do4(t) from receive amplifiers RX[4:1] to recover the originally conveyed bit streams. Destination 140 might be e.g. part of the input/output circuitry in a memory IC.

Reference voltages V+ and V− can be developed locally in receiver 110, or can be sourced externally from e.g. transmitter 105. In one embodiment voltage V+ is calibrated during power-up using test patterns and voltage V− is derived from voltage V+, using an operational amplifier configured as an inverter and referenced from voltage Vio/2 for example. Termination voltage Vio/2 is developed using a local voltage reference 130 in this embodiment, but can also be developed elsewhere in other embodiments. Many methods of establishing and maintaining appropriate reference voltages are well known to those of skill in the art and are therefore omitted for brevity. Further, though omitted for brevity, system 100 can include control circuitry that calibrates and maintains termination resistances and drive currents to maintain optimal voltage swings for signals Da1(t)-Da4(t).

Voltage reference 130 maintains voltage Vio/2 by supplying or drawing a current Iterm from the termination node. Significant magnitudes and fluctuations of current Iterm induce noise on the termination node, and consequently reduce performance. The termination scheme of receiver 110 reduces the magnitude of current Iterm to reduce noise.

The following Table 1 relates each of the 16 possible data patterns Di[4:1] to termination current Iterm. As a simplifying assumption, termination current Iterm is the difference between the sum of the currents Ip1 and Ip2 and the sum of currents In1 and In2 (i.e., Iterm≈Ip1+Ip2−In1−In2). Also for simplicity, the on current for each amplifier T1, T2, T3, and T4 is assumed to be i and the off current zero. Those of skill in the art will appreciate that the precise current Iterm and its relationship to currents Ip1, Ip2, In1, and In2 is more complex than these assumptions, but will readily understand the operation of system 100 based on these illustrations.

Amplifiers T1 and T3 are implemented using PMOS transistors through which current passes when their respective control terminals are presented with relatively low voltages, whereas amplifiers T2 and T4 are implemented using NMOS transistors through which current passes when their respective control terminals are presented with relatively high voltages. Table 1 follows a convention in which data symbols Di[4:1] represent respective logic zero and one symbols using relatively low and high voltages. Logic zero data symbols thus turn amplifiers T1 and T3 on and amplifiers T2 and T4 off.

TABLE 1

| | | | | Drive Current | | | | |
|---|---|---|---|---|---|---|---|---|
| Data Pattern Di1(n)-Di4(n) | | | | Per Amplifier | | | | |
| Di1(n) | Di2(n) | Di3(n) | Di4(n) | Ip1 | In1 | Ip2 | In2 | Iterm |
| 0 | 0 | 0 | 0 | i | 0 | i | 0 | 2i |
| 0 | 0 | 0 | 1 | i | 0 | i | i | i |
| 0 | 0 | 1 | 0 | i | 0 | 0 | 0 | i |
| 0 | 0 | 1 | 1 | i | 0 | 0 | i | 0 |
| 0 | 1 | 0 | 0 | i | i | i | 0 | i |
| 0 | 1 | 0 | 1 | i | i | i | i | 0 |
| 0 | 1 | 1 | 0 | i | i | 0 | 0 | 0 |
| 0 | 1 | 1 | 1 | i | i | 0 | i | −i |
| 1 | 0 | 0 | 0 | 0 | 0 | i | 0 | i |
| 1 | 0 | 0 | 1 | 0 | 0 | i | i | 0 |
| 1 | 0 | 1 | 0 | 0 | 0 | 0 | 0 | 0 |
| 1 | 0 | 1 | 1 | 0 | 0 | 0 | i | −i |
| 1 | 1 | 0 | 0 | 0 | i | i | 0 | 0 |
| 1 | 1 | 0 | 1 | 0 | i | i | i | −i |
| 1 | 1 | 1 | 0 | 0 | i | 0 | 0 | −i |
| 1 | 1 | 1 | 1 | 0 | i | 0 | i | −2i |

Pull-up currents Ip1 and Ip2 flow to termination node Vio/2 at receiver 110 via respective channels 115(1) and 115(3). In contrast, pull-down currents In1 and In2 flow away from termination node Vio/2 via respective channels 115(2) and 115(4), and thus tend to offset the pull-up currents. As illustrated in Table 1, the sum of the drive currents is zero for six of the sixteen possible four-bit symbols, plus or minus i for eight, and plus or minus 2i for the remaining two. In contrast, a similar transmitter implemented using four pull-down amplifiers would draw a worst-case current of 4i from node Vio/2. Receiver 110 thus provides for a factor-of-two reduction in worst-case termination current Item.

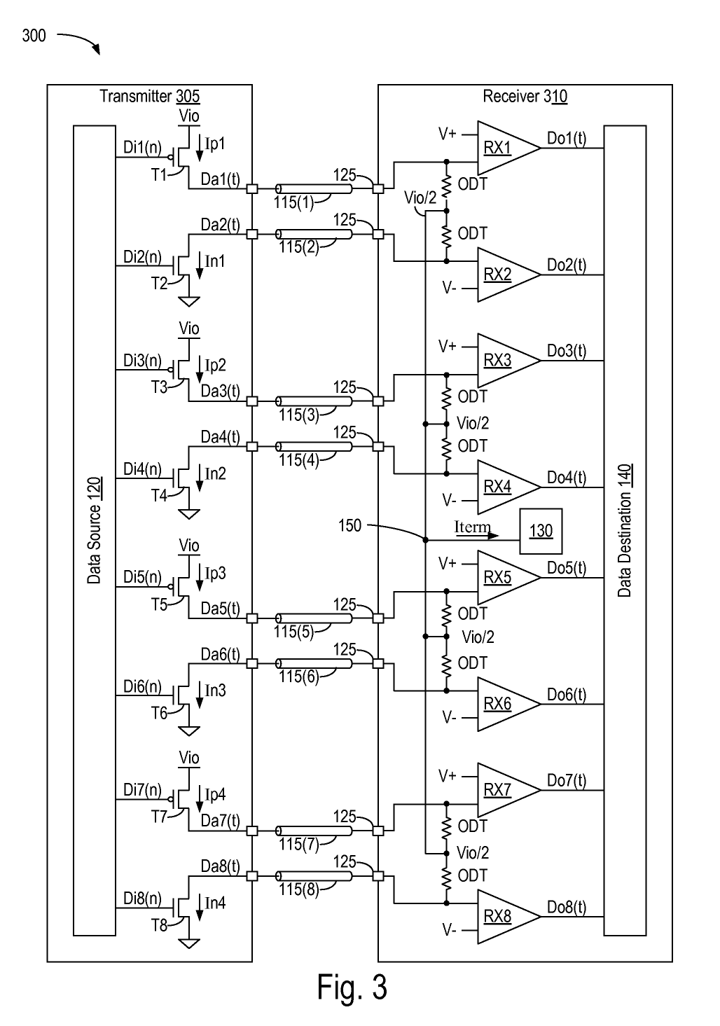

FIG. 3 depicts a system 300 in accordance with an embodiment in which a transmitter 305 communicates with a receiver 310 over an eight-bit bus 115[1:8]. Other than the extension to eight bits, system 300 is like system 100 of FIG. 1, with like-labeled elements being the same or similar. Transmitter 305 conveys eight-bit discrete data slices Di[1:8](n) over respective channels 115[1:8] as continuous-time signals Da[1:8](t), which receiver 310 recovers as output data Do[1:8](t). As described above in connection with FIG. 1, each of amplifiers T1-T8 can be off (non-conducting) or on (conducting) responsive to the state of a respective one of signals Di[1:8](n). Following the convention of Table 1 in which data symbols Di[1:8] represent respective logic zero and one symbols using relatively low and high voltages, logic zero data symbols turn on amplifiers T1, T3, T5, and T7 (the odd amplifiers) and turn off amplifiers T2, T4, T6, and T8 (the even amplifiers). The data pattern Di[1:8](n)=10101010 turns off all of amplifiers T1-T8, and can be used as a resting state to minimize power consumption when e.g. system 300 is not communicating high-speed data.

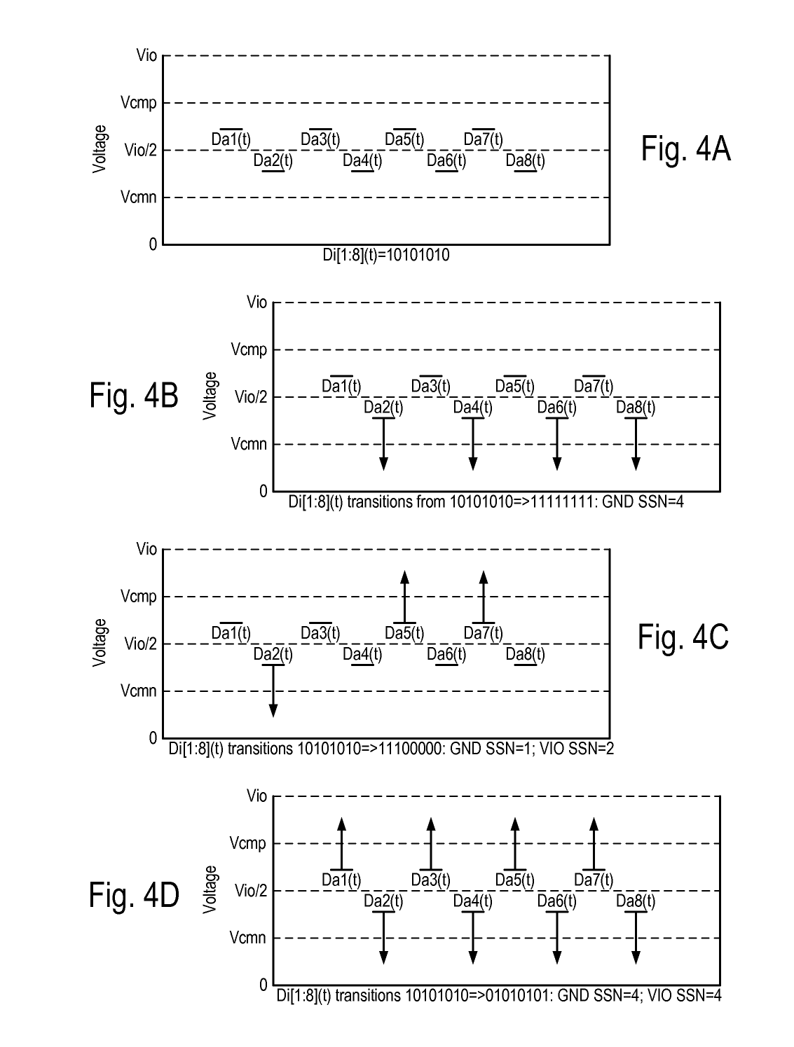

FIGS. 4A-4B illustrate the behavior of continuous-time signals Da[1:8](t) of FIG. 3 in transitioning from the resting state responsive to transitions of discrete signals Di[1:8](n). FIG. 4A represents the resting state. The odd and even bits of bitslice Di[1:8](n) are ones and zeros, respectively, a condition that turns all of amplifiers T[1:8] off. All of signals Da[1:8](t) are thus pulled toward voltage Vio/2. Signals Da[1,3,5,7](t) are therefore below the common-mode voltage Vcmp used for the odd channels and signals Da[2,4,6,8](t) are above the common-mode voltage Vcmn used for even channels.

FIG. 4B depicts the transition of signals Da[1:8](t) from the resting state, in which all amplifiers T1:T8 are off, to a state in which the odd and even amplifiers are off and on, respectively. Turning on the even-numbered amplifiers pulls bits Da[2,4,6,8](t) toward ground, such that the SSN at the ground node of transmitter 305 is 4i, and even signals Da[2,4,6,8](t) are below the common-mode voltage Vcmn used for even channels.

FIG. 4C depicts the transition of signals Da[1:8](t) from the resting state to a state in which amplifiers T2, T5, and T7 are conducting. Turning on one even-numbered amplifier and two odd-numbered amplifiers produces SSN at the ground and Vio nodes of transmitter 305 of i and 2i, respectively.

FIG. 4D depicts the transition of signals Da[1:8](t) from the resting state to a state in which all amplifiers T1-T8 are on. Turning on all of the eight amplifiers produces SSN of 4i at both the ground and Vio nodes of transmitter 305.

The background section above introduced dynamic bus inversion, or DBI, as a coding scheme that adds a ninth bit to eight-bit parallel data to reduce the total current drawn from the power supply for what would otherwise be power-intensive bytes. Assume, for example, an eight-bit parallel bus that conveys logic zero symbols by drawing current from a supply node. The worst-case current in such a case would occur when transmitting eight zero bits in parallel during one UI. Using DBI, the ninth channel is used to invert the bits for each byte that has more zeros then ones. For example, 00000111_{—}1 (the last bit is the DBI bit) becomes 11111000_{—}0. Setting the DBI bit to zero in this example tells the receiver to invert the bits to restore the original byte.

Using DBI in this example reduces the worst-case supply current used to express eight-bit bytes from eight to four (from 8i to 4i). By comparison, the eight-bit embodiment of FIG. 3 provides worst-case supply current to |4i| for each of supply nodes Vio and Gnd at transmitter 105. System 100 thus provides reductions in supply noise similar to that associated with DBI but without the expense, complexity, noise, and power consumption associated with the addition of a ninth bit.

Systems in accordance with other embodiments support coding schemes that take advantage of additional channels to achieve still greater reductions in worst-case supply current. For example, an additional channel can be added, as in the aforementioned DBI technique, to support an additional bit encoded to reduce the worst-case current below |4i|, and thus to achieve better performance than DBI systems having the same number of channels. The additional channel may be implemented using a dedicated additional line or by reusing resources that are normally idle when transmitter 105 is active. The additional channel can use the same or a different signaling scheme. In one embodiment the additional channel is driven by a push-pull amplifier disposed between supply nodes Vio and ground. The push-pull amplifier can then be enabled in either direction to counter current imbalances created by the other channels.

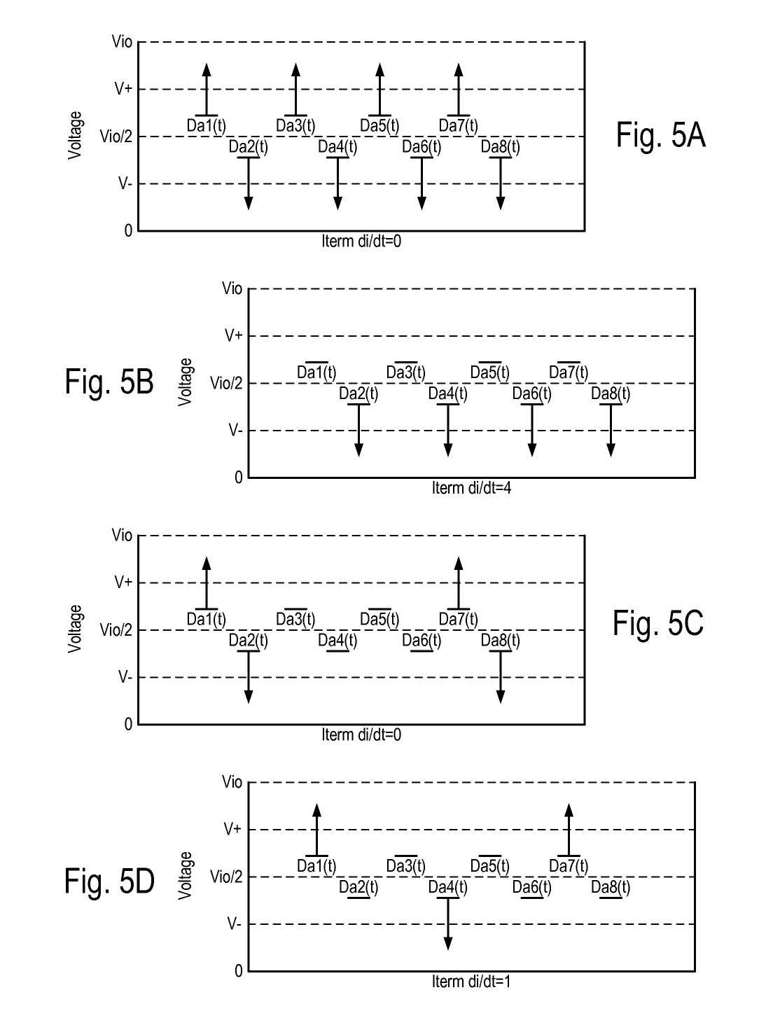

FIGS. 5A-5B illustrate transitions of eight-bit continuous-time signals Da[1:8](t) from the resting state (all amplifiers T1-T8 off) to other states, and shows how such transitions impact the current Iterm at receiver 310. Beginning with FIG. 5A, all of amplifiers T1-T8 transition from non-conducting to conducting, which pulls the four odd data signals high and the four even data signals low. The four high and four low currents sum at node Vio/2, so that the change di/dt of current Iterm is zero (i.e., dIterm/dt=0).

For the transition of FIG. 5B, all of the even amplifiers T2, T4, T6, and T8 transition from non-conducting to conducting, which pulls the four even data signals low: the odd amplifier remain off. The four currents sum at node Vio/2, so that the change di/dt of current Iterm is 4i (i.e., dIterm/dt=4i). FIGS. 5C and 5D represents the cases in which the odd and even amplifiers transition so that Iterm experiences a di/dt of zero and i, respectively.

FIG. 5B represents a worst-case di/dt of 4i. In comparison, an eight-bit channel with eight pull-up or pull-down amplifiers has a worst-case di/dt of 8i. An eight-bit channel that supports DBI has a worst-case di/dt of 4i, but the reduction in di/dt comes with the expense, power-consumption, and complexity of a ninth channel.

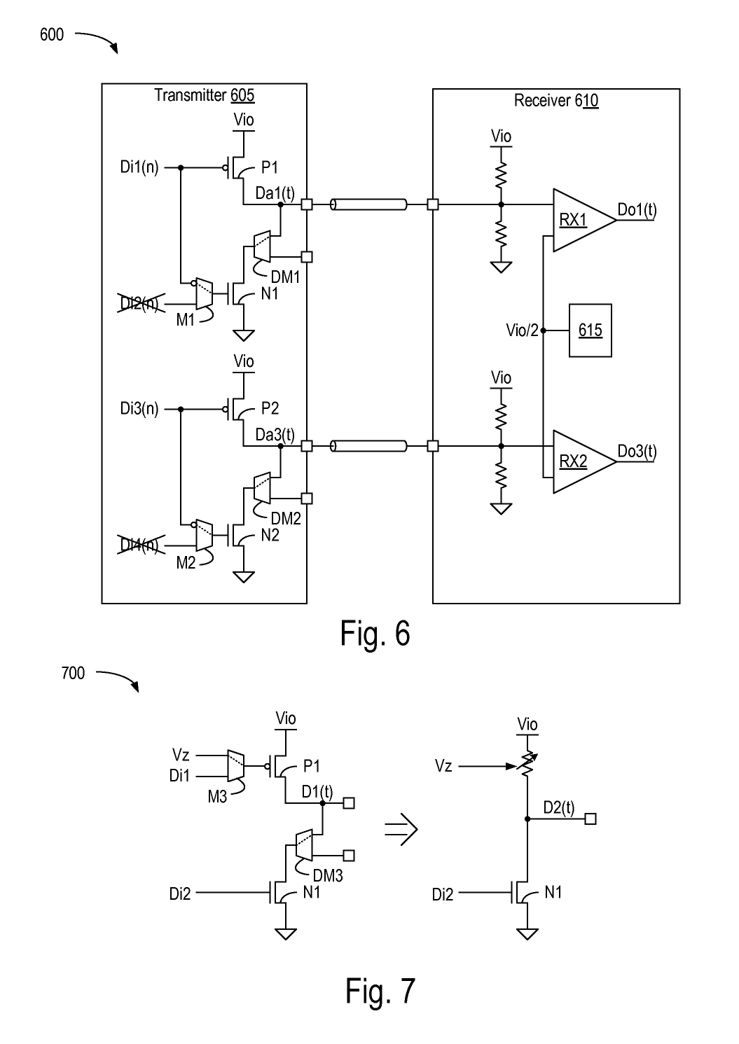

FIG. 6 depicts a system 600 in accordance with an embodiment that is easily rendered compatible with receivers that support conventional communication schemes. Transmitter 605 includes a pair of pull-up transistors P1 and P2, a pair of pull-down transistors N1 and N2, two multiplexers M1 and M2, and two demultiplexers DM1 and DM2. The multiplexers and demultiplexers represent connectivity options, and may be implemented using various programming technologies, including mask programming or register-controlled circuit elements. These multiplexers and demultiplexers can be programmed to provide the same four-bit connectivity and functionality detailed above in connection with transmitter 105 of FIG. 1; alternatively, they can be configured transmitter to support two-bit connectivity using a pair of CMOS amplifiers. This second configuration is thought to provide inferior performance, but advantageously supports a broad range of compatibility.

Dashed lines in multiplexers DM1/2 and multiplexers M1/2 highlight the connectivity selected for the depicted two-channel, push-pull configuration. Transistors P1 and N1 form a CMOS amplifier that drives data signal Di1 to a receiver 605 via a channel 610; transistors P2 and N2 likewise form a CMOS amplifier that drives data signal Di3 to a receiver 605 via a channel 610. Data signals Di2 and Di4 are not used, and the pads associated therewith are not connected to receiver 610.

Receiver 610 can be a conventional receiver, and includes a pair of receive amplifiers RX1 and RX2 connected to respective channels to receive signals D1(t) and D3(t) from transmitter 605. The data terminals of the receive amplifiers include parallel terminations, though other methods of parallel and serial termination might also be used, as will be evident to those of skill in the art. Receive amplifiers RX1 and RX2 compare the incoming signal with a reference voltage Vio/2 from a regulator 615 to obtain output signals Do1(t) and Do3(t), which are then sampled by circuitry omitted from FIG. 6 to recover the original bit streams Di1(n) and Di3(n).

Push-pull circuits like those of the programming option depicted in transmitter 600 have excellent drive characteristics and have been adapted to digital and analog applications as varied as stepping motor control, audio loudspeakers, and memory systems. Ideally, the complementary transistors for each driver switch simultaneously when the output voltage transitions between levels. In practice, however, process variations in the fabrication of the complementary devices, as well as variations in device performance due to operating voltage and temperature variations, prevent the realization of this ideal. As a consequence, it is common for both transistors in a complementary driver to be biased on or off for a very brief instant during output transitions.

Having both transistors momentarily on leads to what is colloquially referred to as “shoot-through” current between the supply nodes at the transmitter. The shoot-through phenomenon wastes power and transmits considerable noise onto the supply terminals and data channel. Having both transistors momentarily off creates a discontinuity in the signal transition that introduces noise on the channel. Considerable effort has been put into solving these problems, and a number of innovative solutions are available. The embodiment of FIG. 1 foregoes complementary drivers, and consequently avoids these problems altogether.

Avoidance of mismatched push and pull drivers is just one advantage of the embodiment of FIG. 1 over the configuration of FIG. 6 when it is configured to function similarly to conventional systems. Also of interest, the output swings of the continuous-time signals Da1(t) and Da3(t) from the complementary configuration of FIG. 6 are greater than the output swings of signals Da1(t)-Da4(t) of the embodiment of FIG. 1. Lower voltage swings reduce power consumption and noise, qualities that are particularly beneficial for the types of mobile communications devices that are becoming ever more popular. The signal swings of transmitters 105 and 605 can be tuned by altering the output impedance of the drive amplifiers, the impedances of termination elements ODT, or both. Embodiments of the systems disclosed herein can be adapted to support rail-to-rail voltage swings (e.g., 0 to 1.8V for Stub Series Terminated Logic), or relatively smaller voltage swings (e.g. less than ±100 mV).

FIG. 7 depicts a driver configuration 700 in accordance with another embodiment. In this example, the control terminal of a pull-up amplifier P1, e.g. the gate of a PMOS transistor, is coupled to a control voltage Vz that can be varied to set the impedance through the transistor. As shown to the right of FIG. 7, the resulting driver is a pull-down amplifier with an adjustable termination impedance to supply node Vio. Embodiments of transmitter 105 of FIG. 1 can be easily adapted to support this programming option as well.

In the foregoing description and in the accompanying drawings, specific terminology and drawing symbols are set forth to provide a thorough understanding of the present invention. In some instances, the terminology and symbols may imply specific details that are not required to practice the invention. For example, circuits described or depicted as including metal oxide semiconductor (MOS) transistors may alternatively be implemented using bipolar technology or any other technology in which a signal-controlled current flow may be achieved.

An output of a process for designing an integrated circuit, or a portion of an integrated circuit, comprising one or more of the circuits described herein may be a computer-readable medium such as, for example, a magnetic tape or an optical or magnetic disk. The computer-readable medium may be encoded with data structures or other information describing circuitry that may be physically instantiated as an integrated circuit or portion of an integrated circuit. Although various formats may be used for such encoding, these data structures are commonly written in Caltech Intermediate Format (CIF), Calma GDS II Stream Format (GDSII), or Electronic Design Interchange Format (EDIF). Those of skill in the art of integrated circuit design can develop such data structures from schematic diagrams of the type detailed above and the corresponding descriptions and encode the data structures on computer readable medium. Those of skill in the art of integrated circuit fabrication can use such encoded data to fabricate integrated circuits comprising one or more of the circuits described herein.

While the present invention has been described in connection with specific embodiments, variations of these embodiments will be obvious to those of ordinary skill in the art. For example, the unidirectional, point-to-point, chip-to-chip embodiments detailed previously are easily extensible to bidirectional systems, multi-drop buses, and to communication within and between larger or smaller systems. Furthermore, the advantages provided by the amplifiers and receivers depicted above can be extended to other types of signals. For example, continuous-time clock signals conveyed in parallel on an integrated circuit can suffer from SSN and may benefit from the solutions provided herein. In still other embodiments the transmitted signals can be multi-pulse-amplitude-modulated (multi-PAM) signals.

Moreover, some components are shown directly connected to one another while others are shown connected via intermediate components. In each instance the method of interconnection, or “coupling,” establishes some desired electrical communication between two or more circuit nodes, or terminals. Such coupling may often be accomplished using a number of circuit configurations, as will be understood by those of skill in the art. Therefore, the spirit and scope of the appended claims should not be limited to the foregoing description. Only those claims specifically reciting “means for” or “step for” should be construed in the manner required under the sixth paragraph of 35 U.S.C. Section 112.

What is claimed is:

1. A transmitter comprising:
first and second voltage nodes to respectively provide relatively high and low voltages;
a signal source to provide a plurality of parallel signal streams, including a first signal stream and a second signal stream;
a pull-up amplifier having a first control terminal coupled to the signal source to receive the first signal stream, a first current-handling terminal coupled to the first voltage node to receive the relatively high voltage level, and a second current-handling terminal to provide an amplified version of the first signal stream as a first continuous-time output signal, the first continuous-time output signal having a first common-mode voltage; and
a pull-down amplifier having a second control terminal coupled to the signal source to receive the second signal stream, a third current-handling terminal coupled to the second voltage node to receive the relatively low voltage level, and a fourth current-handling terminal to provide an amplified version of the second signal stream as a second continuous-time output signal, the second continuous-time output signal having a second common-mode voltage between the first common-mode voltage and the low voltage.

2. The transmitter of claim 1, wherein the first continuous-time output signal has a first voltage swing, the second continuous-time output signal has a second voltage swing, and a difference between the first common-mode voltage and a mid-level between the relatively high and low voltages is greater than half the first voltage swing.

3. The transmitter of claim 2, wherein a second difference between the second common-mode voltage and the mid-level between the relatively high and low voltages is greater than half the second voltage swing.

4. The transmitter of claim 3, wherein the first and second voltage swings are about equal.

5. The transmitter of claim 1, further comprising a first signal pad coupled to the second current-handling terminal to convey the amplified version of the first signal stream and a second signal pad, adjacent the first signal pad, coupled to the fourth current-handling terminal to convey the amplified version of the second signal stream.

6. The transmitter of claim 1, wherein the first and second signal streams are discrete signals.

7. A receiver to receive a plurality of parallel continuous-time signals on a corresponding plurality of terminals, including a first terminal to receive a first continuous-time signal and a second terminal to receive a second continuous-time signal in parallel with the first continuous-time signal, the receiver comprising:
first and second reference-voltage nodes to respectively provide relatively high and low reference voltages;
a termination node to receive a termination voltage between the high and low reference voltages;
a first termination impedance disposed between the termination node and the first terminal;
a second termination impedance disposed between the termination node and the second terminal;
a first receive amplifier having a first reference node coupled to the first reference-voltage node, to receive the relatively high reference voltage, and a first input node coupled to the first terminal to receive the first continuous-time signal; and
a second receive amplifier having a second reference node coupled to the second reference-voltage node, to receive the relatively low reference voltage, and a second input node coupled to the second terminal to receive the second continuous-time signal.

8. The receiver of claim 7, wherein the first continuous-time signal has a first voltage swing, the second continuous-time signal has a second voltage swing, and a difference between the first common-mode voltage and the termination voltage is greater than half the first voltage swing.

9. The receiver of claim 8, wherein a second difference between the second common-mode voltage and the termination voltage is greater than half the second voltage swing.

10. The receiver of claim 9, wherein the first and second voltage swings are about equal.

11. The receiver of claim 7, wherein the first and second terminals are adjacent pads on a integrated circuit.

12. A parallel communication system comprising:
at least two sets of single-ended communication channels, including a first set of channels to convey a first set of continuous-time signals and a second set of channels to convey a second set of continuous-time signals;
wherein each of the first set of continuous-time signals has a first voltage swing and a first common-mode voltage and each of the second set of continuous-time signals has a second voltage swing and a second common-mode voltage; and
wherein the difference between the first and second common-mode voltages is greater than half the sum of the first and second voltage swings.

13. The communication system of claim 12, wherein each member of the first set of communication channels is physically separated from the other members of the first set of communication channels by one or more members of the second set of communication channels.

14. The communication system of claim 12, further comprising a pull-up amplifier coupled to each of the first set of communication channels to express the first set of continuous-time signals and a pull-down amplifier coupled to each of the second set of communication channels to express the second set of continuous-time signals.

15. The communication system of claim 12, further comprising a receiver having a first set of receive amplifiers referenced to a relatively high voltage coupled to the first set of channels to receive the first set of signals and a second set of receive amplifiers referenced to a relatively low voltage coupled to the second set of channels to receive the second set of signals.

16. The communication system of claim 15, the receiver further having a termination resistor connecting each channel to a termination voltage between the first and second common-mode voltages.

17. A method of conveying parallel bit streams, including first and second sets of bit streams, simultaneously over parallel communication channels, the method comprising:
terminating the communication channels to a termination node;
selectively applying current to the termination node via a first subset of the communication channels and responsive to the first set of bit streams to produce a first set of continuous-time signals having a first common-mode voltage; and
selectively drawing current from the termination node via a second subset of the communication channels and responsive to the second set of bit streams to produce a second set of continuous-time signals having a second common-mode voltage.

18. The method of claim 17, wherein a first one of the first set of continuous-time signals has a first voltage swing and a second one of the second set of continuous-time signals has a second voltage swing, the sum of the first and second voltage swings being less than a voltage difference between the first and second common-mode voltages.

19. The method of claim 17, wherein selectively applying current to the termination node via the first subset of the communication channels comprises pulling at least one of the first subset of the communication channels up toward a first supply voltage and selectively drawing current from the termination node via the second subset of the communication channels comprises pulling at least one of the second subset of the communication channels down toward a second supply voltage.

20. The method of claim 17, further comprising comparing the first set of continuous-time signals with a first reference voltage to recover the first set of bit streams and comparing the second set of continuous-time signals with a second reference voltage to recover the second set of bit streams.

21. The method of claim 20, wherein the first reference voltage approximates the first common-mode voltage and the second reference voltage approximates the second common-mode voltage.
